(19) United States
(12) Patent Application Publication
(10) Pub. No.: US 2025/0080058 A1
(43) Pub. Date: Mar. 6, 2025

(54) HIGH FREQUENCY MODULE AND COMMUNICATION APPARATUS

(71) Applicant: Murata Manufacturing Co., Ltd., Kyoto (JP)

(72) Inventor: Teruaki OSHITA, Kyoto (JP)

(21) Appl. No.: 18/747,559

(22) Filed: Jun. 19, 2024

(30) Foreign Application Priority Data
Sep. 4, 2023 (JP) 2023-143047

(51) Int. Cl. H03F 1/56; H03F 3/19; H04B 1/04

(52) U.S. Cl. CPC H03F 1/565; H03F 3/19; H04B 1/04; H03F 2200/222; H03F 2200/294; H03F 2200/387; H03F 2200/451

(57) ABSTRACT

A high frequency module includes a first reception filter, a second reception filter, a first low noise amplifier, a first inductor, a second inductor, and a mounting substrate. The first reception filter, the second reception filter, the first inductor, and the second inductor are disposed on a first main surface of the mounting substrate. When seen in plan view from a thickness direction of the mounting substrate, an outer size of the first inductor is larger than an outer size of the second inductor. The first inductor includes a first part around which part of a wire is closely wound and a second part around which a remaining part of the wire is sparsely wound. In an orthogonal direction that is orthogonal to the thickness direction, the first part of the first inductor and the first reception filter do not overlap.

### CROSS REFERENCE TO RELATED APPLICATION

This application claims priority from Japanese Patent Application No. 2023-143047 filed on Sep. 4, 2023. The content of this application is incorporated herein by reference in its entirety.

### BACKGROUND ART

The present disclosure relates in general to a high frequency module and a communication apparatus, and more particularly, to a high frequency module including a plurality of filters and a plurality of inductors and a communication apparatus including the high frequency module.

A high frequency module including a plurality of filters and a plurality of inductors is described in International Publication No. 2018/110577. In the high frequency module described in International Publication No. 2018/110577, inductors are arranged at input/output parts of the individual filters, so that impedance adjustment can be performed for the individual filters.

### BRIEF SUMMARY

In the high frequency module described in International Publication No. 2018/110577, attenuation characteristics of the filters may be deteriorated depending on the arrangement and orientation of the inductors at a mounting substrate at which the plurality of filters and the plurality of inductors are mounted.

The present disclosure provides a high frequency module and a communication apparatus capable of reducing a deterioration in attenuation characteristics of a filter.

A high frequency module according to an aspect of the present disclosure includes a first reception filter, a second reception filter, a first low noise amplifier, a first inductor, a second inductor, and a mounting substrate. The first reception filter has a pass band including a first reception band. The second reception filter has a pass band including a second reception band that is different from the first reception band. The first inductor includes a core and a wire and is connected between the first reception filter and the first low noise amplifier. The second inductor is connected to an output terminal of the second reception filter. The mounting substrate has a first main surface and a second main surface that are opposite to each other. The first reception filter, the second reception filter, the first inductor, and the second inductor are disposed on the first main surface of the mounting substrate. An outer size of the first inductor is larger than an outer size of the second inductor when seen in plan view from a thickness direction of the mounting substrate. The first inductor includes a first part around which part of the wire is closely wound, and a second part around which a remaining part of the wire is sparsely wound. In an orthogonal direction that is orthogonal to the thickness direction, the first part of the first inductor and the first reception filter do not overlap.

A high frequency module according to another aspect of the present disclosure includes a first reception filter, a second reception filter, a first low noise amplifier, a first inductor, a second inductor, and a mounting substrate. The first reception filter has a pass band including a first reception band. The second reception filter has a pass band including a second reception band that is different from the first reception band. The first inductor includes a core and a wire and is connected between the first reception filter and the first low noise amplifier. The second inductor is connected to an output terminal of the second reception filter. The mounting substrate has a first main surface and a second main surface that are opposite to each other. The first reception filter, the second reception filter, the first inductor, and the second inductor are disposed on the first main surface of the mounting substrate. When seen in plan view from a thickness direction of the mounting substrate, an outer size of the first inductor is larger than an outer size of the second inductor. When seen in plan view from the thickness direction, in a first direction that is orthogonal to the thickness direction, the first reception filter and the second reception filter are arranged next to each other. When seen in plan view from the thickness direction, in a second direction that is orthogonal to both the thickness direction and the first direction, the second reception filter and the first inductor are arranged next to each other and the first reception filter and the second inductor are arranged next to each other.

A communication apparatus according to an aspect of the present disclosure includes the high frequency module and a signal processing circuit. The signal processing circuit is connected to the high frequency module.

With a high frequency module and a communication apparatus according to an aspect of the present disclosure, a deterioration in attenuation characteristics of a filter can be reduced.

### BRIEF DESCRIPTION OF THE DRAWINGS

FIG. 1 is a circuit configuration diagram of a communication apparatus including a high frequency module according to a first embodiment;

FIG. 2 is a plan view of the high frequency module;

FIG. 3 is a bottom view of the high frequency module;

FIG. 4 is a plan view of a high frequency module according to a modification of the first embodiment;

FIG. 5 is a graph indicating attenuation characteristics of the high frequency module according to the first embodiment and attenuation characteristics of the high frequency module according to the modification of the first embodiment;

FIG. 6 is a plan view of a high frequency module according to a second embodiment;

FIG. 7 is a plan view of a high frequency module according to a third embodiment; and

FIG. 8 is a plan view of a high frequency module according to a fourth embodiment.

### DETAILED DESCRIPTION

First to fourth embodiments will be described below with reference to drawings. The drawings referenced in the embodiments and others are schematic diagrams. Sizes and thicknesses of component elements in the drawings do not necessarily reflect the actual dimensions. The size ratio and the thickness ratio of component elements do not necessarily reflect the actual dimension ratio.

### FIRST EMBODIMENT

### 1 High Frequency Module

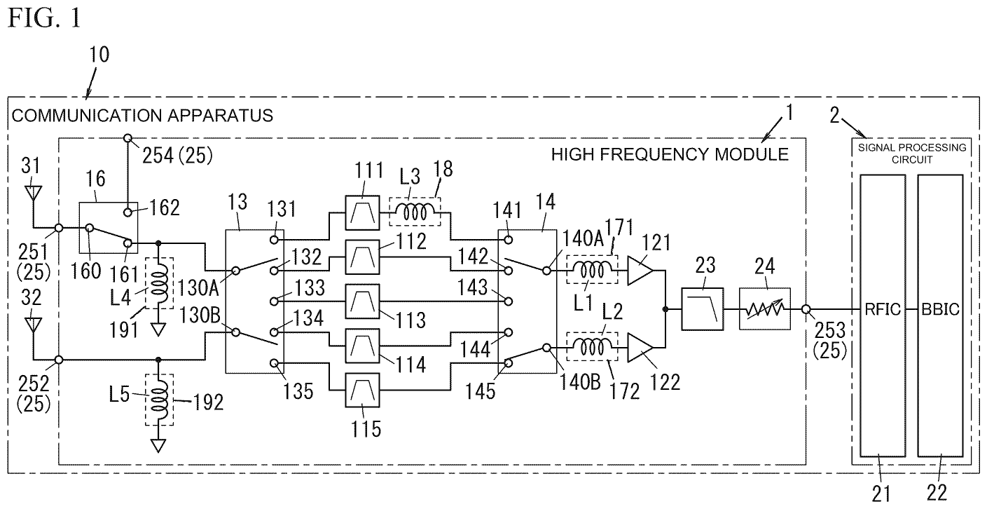

First, a configuration of a high frequency module 1 according to a first embodiment will be described with reference to FIG. 1.

As illustrated in FIG. 1, the high frequency module 1 is used in, for example, a communication apparatus 10. The communication apparatus 10 is, for example, a mobile phone such as a smartphone. The communication apparatus 10 is not limited to a mobile phone and may be, for example, a wearable terminal such as a smartwatch. The high frequency module 1 is, for example, a module capable of supporting fourth-generation mobile communication (4G) standards, fifth-generation mobile communication (5G) standards, and the like. The 4G standards are, for example, Third Generation Partnership Project (3GPP) (registered trademark)) Long Term Evolution (LTE) (registered trademark)) standards. The 5G standards are, for example, 5G New Radio (NR). The high frequency module 1 is, for example, a module capable of supporting carrier aggregation and dual connectivity.

In the communication apparatus 10, the high frequency module 1 as a reception module receives a reception signal. Furthermore, the communication apparatus 10 transmits a transmission signal from a transmission module (not illustrated in the drawing) input, via a signal input terminal 254, which will be described later, to the high frequency module 1. For example, the communication apparatus 10 switches every certain period of time between transmission and reception. In the case where a reception signal and a transmission signal are signals in the same frequency range, these signals are time division duplex (TDD) signals. TDD represents a wireless communication technique for allocating the same frequency range to transmission and reception in wireless communication and switching every certain period of time between transmission and reception. Part of transmission signals and reception signals in the communication apparatus 10 may be frequency division duplex (FDD) signals. FDD represents a wireless communication technique for performing transmission and reception by allocating different frequency ranges to transmission and reception in wireless communication.

### 2 Circuit Configuration of High Frequency Module

Next, a circuit configuration of the high frequency module 1 according to the first embodiment will be described with reference to FIG. 1.

As illustrated in FIG. 1, the high frequency module

1 includes a plurality of (in the example illustrated in the drawing, five) reception filters 111 to 115, a plurality of (in the example illustrated in the drawing, two) low noise amplifiers 121 and 122, and a plurality of (in the example illustrated in the drawing, three) switches 13, 14, and 16. Furthermore, the high frequency module 1 further includes a plurality of (in the example illustrated in the drawing, two) input matching circuits 171 and 172, a plurality of (in the example illustrated in the drawing, three) matching circuits 18, 191, and 192, a low pass filter 23, and an attenuator 24. Furthermore, the high frequency module 1 further includes a plurality of (in the example illustrated in the drawing, four) external connection terminals 25. In the first embodiment, the high frequency module 1 is a reception module. However, the high frequency module 1 may be a transmission/reception module that further includes a transmission filter, a power amplifier, and the like.

### 2.1 Reception Filters

Each of the plurality of reception filters 111 to 115 is a filter that passes reception signals. For example, the reception filter 111 has a pass band including a second reception band. For example, the reception filter 112 has a pass band including a third reception band. For example, the reception filter 113 has a pass band including a fourth reception band. For example, the reception filter 114 has a pass band including a fifth reception band. For example, the reception filter 115 has a pass band including a first reception band.

The first reception band is, for example, Band 26 based on the 3GPP LTE standards. The second reception band is, for example, Band 71 based on the 3GPP LTE standards. The third reception band is, for example, Band 12 based on the 3GPP LTE standards. The fourth reception band is, for example, Band 14 based on the 3GPP LTE standards. The fifth reception band is, for example, Band 20 based on the 3GPP LTE standards. In the high frequency module 1 according to the first embodiment, the reception filter 115 corresponds to a first reception filter, and the reception filter 111 corresponds to a second reception filter.

In the high frequency module 1 according to the first embodiment, the first reception band is Band 26. However, the first reception band may be, for example, Band 8, Band 12, Band 29, Band 13, Band 14, Band 28, or Band 20.

Each of the plurality of reception filters 111 to 115 includes an acoustic wave filter. The acoustic wave filter includes a plurality of acoustic wave resonators. Each of the plurality of acoustic wave resonators is a surface acoustic wave (SAW) resonator. The plurality of reception filters 111 to 115 are not necessarily acoustic wave filters and may be, for example, bulk acoustic wave (BAW) filters.

### 2.2 Low Noise Amplifiers

Each of the plurality of low noise amplifiers 121 and 122 is an amplifier that amplifies reception signals with low noise. The low noise amplifier 121 is connected between the reception filters 111 to 113 and a signal output terminal 253, which will be described later. The low noise amplifier 122 is connected between the reception filters 114 and 115 and the signal output terminal 253. In the high frequency module 1 according to the first embodiment, the low noise amplifier 121 corresponds to a second low noise amplifier, and the low noise amplifier 122 corresponds to a first low noise amplifier.

Each of the low noise amplifiers 121 and 122 includes an input terminal (not illustrated in the drawing) and an output terminal (not illustrated in the drawing). The input terminal of the low noise amplifier 121 is connected to the input matching circuit 171. The output terminal of the low noise amplifier 121 is connected to the low pass filter 23. Furthermore, the output terminal of the low noise amplifier 121 is connected to an external circuit (for example, a signal processing circuit 2) with the low pass filter 23, the attenuator 24, and the signal output terminal 253 interposed therebetween. The input terminal of the low noise amplifier 122 is connected to the input matching circuit 172. The output terminal of the low noise amplifier 122 is connected to the low pass filter 23. Furthermore, the output terminal of the low noise amplifier 122 is connected to an external circuit (for example, the signal processing circuit 2) with the low pass filter 23, the attenuator 24, and the signal output terminal 253 interposed therebetween.

### 2.3 Switches

The switch 13 includes two common terminals 130A and 130B and five selection terminals 131 to 135. The switch 13 switches between connection and disconnection between the common terminal 130A and at least one of the five selection terminals 131 to 135 and switches between connection and disconnection between the common terminal 130B and at least one of the five selection terminals 131 to 135. The common terminal 130A is connected to a first antenna terminal 251, which will be described later, with the switch 16 interposed therebetween. The common terminal 130B is connected to a second antenna terminal 252, which will be described later. The selection terminal 131 is connected to the input terminal of the reception filter 111. The selection terminal 132 is connected to the input terminal of the reception filter 112. The selection terminal 133 is connected to the input terminal of the reception filter 113. The selection terminal 134 is connected to the input terminal of the reception filter 114. The selection terminal 135 is connected to the input terminal of the reception filter 115. In the high frequency module 1 according to the first embodiment, the first antenna terminal 251 and the second antenna terminal 252 correspond to antenna terminals, and the switch 13 corresponds to a second switch.

The switch 14 includes two common terminals 140A and 140B and five selection terminals 141 to 145. The switch 14 switches between connection and disconnection between the common terminal 140A and at least one of the five selection terminals 141 to 145 and switches between connection and disconnection between the common terminal 140B and at least one of the five selection terminals 141 to 145. The common terminal 140A is connected to the input terminal of the low noise amplifier 121 with the input matching circuit 171 interposed therebetween. The common terminal 140B is connected to the input terminal of the low noise amplifier 122 with the input matching circuit 172 interposed therebetween. The selection terminal 141 is connected to the output terminal of the reception filter 111 with the matching circuit 18 interposed therebetween. The selection terminal 142 is connected to the output terminal of the reception filter 112. The selection terminal 143 is connected to the output terminal of the reception filter 113. The selection terminal 144 is connected to the output terminal of the reception filter 114. The selection terminal 145 is connected to the output terminal of the reception filter 115. In the high frequency module 1 according to the first embodiment, the switch 14 corresponds to a first switch (switch), the common terminal 140B corresponds to a first common terminal, the common terminal 140A corresponds to a second common terminal, the selection terminal 145 corresponds to a first selection terminal, and the selection terminal 141 corresponds to a second selection terminal.

The switch 16 includes a common terminal 160 and two selection terminals 161 and 162. The common terminal 160 is connected to the first antenna terminal 251. The selection terminal 161 is connected to the common terminal 130A of the switch 13. The selection terminal 162 is connected to the signal input terminal 254, which will be described later. The switch 16 includes an SPDT switch circuit.

### 2.4 Input Matching Circuits

The input matching circuit 171 includes an inductor L1. The inductor L1 of the input matching circuit 171 is provided near the input side of the low noise amplifier 121. More particularly, the inductor L1 is connected between the common terminal 140A of the switch 14 and the input terminal of the low noise amplifier 121. Furthermore, the inductor L1 is connected between the reception filter 111 and the low noise amplifier 121. The input matching circuit 171 performs impedance matching between the switch 14 and the low noise amplifier 121.

The input matching circuit 172 includes an inductor L2. The inductor L2 of the input matching circuit 172 is provided near the input side of the low noise amplifier 122. More particularly, the inductor L2 is connected between a common terminal 140B of the switch 14 and the input terminal of the low noise amplifier 122. Furthermore, the inductor L2 is connected between the reception filter 115 and the low noise amplifier 122. The input matching circuit 172 performs impedance matching between the switch 14 and the low noise amplifier 122.

The input matching circuit 171 does not necessarily include one inductor L1. For example, the input matching circuit 171 may include a plurality of inductors or may include a plurality of inductors and a plurality of capacitors. Furthermore, the input matching circuit 172 does not necessarily include one inductor L2. For example, the input matching circuit 172 may include a plurality of inductors or may include a plurality of inductors and a plurality of capacitors. In the high frequency module 1 according to the first embodiment, the inductor L2 of the input matching circuit 172 corresponds to a first inductor, and the inductor L1 of the input matching circuit 171 corresponds to a third inductor.

### 2.5 Matching Circuits

The matching circuit 18 includes an inductor L3. The inductor L3 of the matching circuit 18 is connected between the output terminal of the reception filter 111 and the selection terminal 141 of the switch 14. The matching circuit 18 performs impedance matching between the reception filter 111 and the switch 14. In the high frequency module 1 according to the first embodiment, the inductor L3 of the matching circuit 18 corresponds to a second inductor.

The matching circuit 191 includes an inductor L4. The inductor L4 of the matching circuit 191 is connected between a path between the common terminal 130A of the switch 13 and the selection terminal 161 of the switch 16 and the ground. The matching circuit 191 performs impedance matching between the switch 13 and the switch 16.

The matching circuit 192 includes an inductor L5. The inductor L5 of the matching circuit 192 is connected between a path between the second antenna terminal 252 and the common terminal 130A of the switch 13 and the ground. The matching circuit 192 performs impedance match between a second antenna 32, which will be described later, and the switch 13.

The matching circuit 18 does not necessarily include one inductor L3. For example, the matching circuit 18 may include a plurality of inductors or may include a plurality of inductors and a plurality of capacitors. Furthermore, the matching circuit 191 does not necessarily include one inductor L4. For example, the matching circuit 191 may include a plurality of inductors or may include a plurality of inductors and a plurality of capacitors. Furthermore, the matching circuit 192 does not necessarily include one inductor L5. For example, the matching circuit 192 may include a plurality of inductors or may include a plurality of inductors and a plurality of capacitors.

### 2.6 Low Pass Filter

The low pass filter 23 is, for example, an LC filter. The low pass filter 23 has a pass band including the first reception band, the second reception band, the third reception band, the fourth reception band, and the fifth reception band described above.

### 2.7 Attenuator

The attenuator 24 is connected between the low pass filter 23 and the signal output terminal 253. The attenuator 24 attenuates a reception signal received via a first antenna 31 or the second antenna 32, which will be described later, to a predetermined signal level.

### 2.8 External Connection Terminals

As illustrated in FIG. 1, the plurality of external connection terminals 25 are terminals for electrically connecting to an external circuit (for example, the signal processing circuit 2). The plurality of external connection terminals 25 include the first antenna terminal 251, the second antenna terminal 252, the signal output terminal 253, the signal input terminal 254, and a plurality of ground terminals (not illustrated in the drawing).

The first antenna terminal 251 is connected to the first antenna 31. In the high frequency module 1, the first antenna terminal 251 is connected to the common terminal 160 of the switch 16. The second antenna terminal 252 is connected to the second antenna 32. In the high frequency module 1, the second antenna terminal 252 is connected to the common terminal 130B of the switch 13.

The signal output terminal 253 is a terminal for outputting to an external circuit (for example, the signal processing circuit 2) a reception signal input to the high frequency module 1 via the first antenna terminal 251 and the second antenna terminal 252. In the high frequency module 1, the signal output terminal 253 is connected to the attenuator 24.

The signal input terminal 254 is a terminal for inputting to the high frequency module 1 a transmission signal from an external circuit (for example, a transmission module, which is not illustrated in the drawing). In the high frequency module 1, the signal input terminal 254 is connected to the selection terminal 162 of the switch 16. Furthermore, the signal input terminal 254 is connected to the first antenna terminal 251 with the switch 16 interposed therebetween.

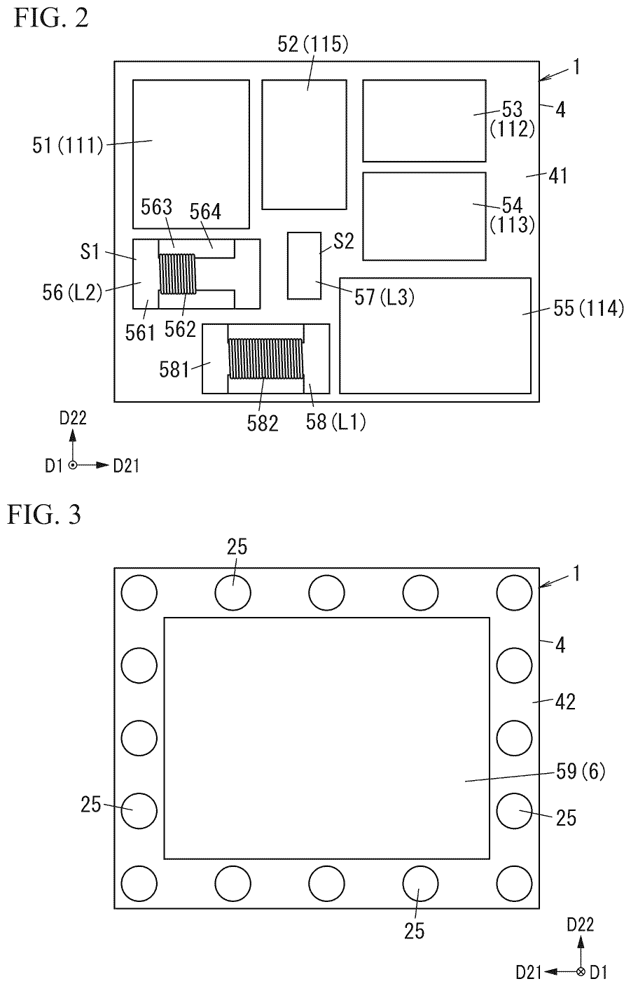

The plurality of ground terminals are terminals that are electrically connected to ground electrodes at an external substrate (not illustrated in the drawing) included in the communication apparatus 10, and ground potential is supplied to the plurality of ground terminals. In the high frequency module 1, the plurality of ground terminals are connected to a ground layer (not illustrated in the drawing) of a mounting substrate 4 (see FIG. 2). The ground layer is a circuit ground of the high frequency module 1.

### 3 Circuit Configuration of Communication Apparatus

Next, a circuit configuration of the communication apparatus 10 according to the first embodiment will be described with reference to FIG. 1.

As illustrated in FIG. 1, the communication apparatus 10 according to the first embodiment includes the high frequency module 1, the signal processing circuit 2, the first antenna 31, and the second antenna 32. The signal processing circuit 2 is connected to the high frequency module 1.

### 3.1 Signal Processing Circuit

The signal processing circuit 2 includes an RF signal processing circuit 21 and a baseband signal processing circuit 22.

The RF signal processing circuit 21 is, for example, a radio frequency integrated circuit (RFIC). For example, the RF signal processing circuit 21 performs signal processing such as up-conversion for a high frequency signal (transmission signal) output from the baseband signal processing circuit 22 and outputs the high frequency signal on which the signal processing has been performed. Furthermore, for example, the RF signal processing circuit 21 performs signal processing such as down-conversion for a high frequency signal (reception signal) output from the high frequency module 1 and outputs the high frequency signal on which the signal processing has been performed to the baseband signal processing circuit 22.

The baseband signal processing circuit 22 is, for example, a baseband integrated circuit (BBIC). The baseband signal processing circuit 22 generates an I-phase signal and a Q-phase signal from a baseband signal. The baseband signal is, for example, an audio signal or an image signal input from the outside. The baseband signal processing circuit 22 performs IQ modulation processing by combining the I-phase signal and the Q-phase signal and outputs a transmission signal. At this time, the transmission signal is generated as a modulation signal (IQ signal) for amplitude modulation of a carrier signal at a predetermined frequency, the amplitude modulation being performed at a period longer than the period of the carrier signal. For example, a reception signal processed by the baseband signal processing circuit 22 is used as an image signal for the purpose of image display or used as an audio signal for the purpose of conversion by a user of the communication apparatus 10.

### 3.2 Antenna

The first antenna 31 is connected to the first antenna terminal 251 of the high frequency module 1. The second antenna 32 is connected to the second antenna terminal 252 of the high frequency module 1. Each of the first antenna 31 and the second antenna 32 has a reception function for receiving a reception signal as a radio wave from the outside and outputting the reception signal to the high frequency module 1. Furthermore, the first antenna 31 further has a transmission function for emitting, as a radio wave, a transmission signal input to the high frequency module 1 via the signal input terminal 254.

### 4 Structure of High Frequency Module

Next, a structure of the high frequency module 1 according to the first embodiment will be described with reference to FIGS. 2 and 3.

As illustrated in FIGS. 2 and 3, the high frequency module 1 includes the mounting substrate 4, first to ninth electronic components 51 to 59, and the plurality of (in the example illustrated in the drawing, sixteen) external connection terminals 25. The high frequency module 1 further includes a first resin layer (not illustrated in the drawing), a second resin layer (not illustrated in the drawing), and a metal electrode layer (not illustrated in the drawing).

The high frequency module 1 can be electrically connected to an external substrate (not illustrated in the drawing). The external substrate corresponds to, for example, a motherboard of the communication apparatus 10 (see FIG. 1) such as a mobile phone or communication equipment. The state in which the high frequency module 1 can be electrically connected to an external substrate represents not only a case where the high frequency module 1 is mounted directly on the external substrate but also a case where the high frequency module 1 is mounted indirectly on the external substrate. Furthermore, the case where the high frequency module 1 is mounted indirectly on the external substrate represents a case where the high frequency module 1 is mounted on another high frequency module mounted on the external substrate or other cases.

### 4.1 Mounting Substrate

As illustrated in FIGS. 2 and 3, the mounting substrate 4 has a first main surface 41 and a second main surface 42 that are opposite to each other in a thickness direction D1 of the mounting substrate 4. The outer edge of the mounting substrate 4 has, for example, a rectangular shape when seen in plan view from the thickness direction D1 of the mounting substrate 4. However, the outer edge of the mounting substrate 4 may have a shape different from the rectangular shape. For example, the mounting substrate 4 is a multilayer substrate in which a plurality of dielectric layers (not illustrated in the drawing) and a plurality of conductive layers (not illustrated in the drawing) are laminated. The plurality of conductive layers are formed in predetermined patterns set for individual layers. Each of the plurality of conductive layers includes one or a plurality of conductor parts on a plane that is orthogonal to the thickness direction D1 of the mounting substrate 4. A material of each of the conductive layers is, for example, copper. The plurality of conductive layers include a ground layer. The ground layer of the mounting substrate 4 is electrically connected to at least one ground terminal included in the plurality of external connection terminals 25 with a via conductor or other elements of the mounting substrate 4 interposed therebetween.

The mounting substrate 4 is, for example, a low temperature co-fired ceramics (LTCC) substrate. The mounting substrate 4 is not limited to an LTCC substrate and may be, for example, a printed wiring board, a high temperature co-fired ceramics (HTCC) substrate, a resin multilayer substrate, or a component built-in substrate.

The first to eighth electronic components 51 to 58 are disposed on the first main surface 41 of the mounting substrate 4. The ninth electronic component 59 is disposed on the second main surface 42 of the mounting substrate 4. “An electronic component is disposed the first main surface 41 of the mounting substrate 4” includes the state in which the electronic component is mounted on (mechanically connected to) the first main surface 41 of the mounting substrate 4 and the state in which the electronic component is electrically connected to (an appropriate conductor part of) the mounting substrate 4. “An electronic component is disposed on the second main surface 42 of the mounting substrate 4” includes the state in which the electronic component is mounted on (mechanically connected to) the second main surface 42 of the mounting substrate 4 and the state in which the electronic component is electrically connected to (an appropriate conductor part of) the mounting substrate 4. The outer edge of each of the first to ninth electronic components 51 to 59 has, for example, a rectangular shape when seen in plan view from the thickness direction D1 of the mounting substrate 4.

In FIGS. 2 and 3, illustration of electronic components configuring the switches 13, 14, and 16, the matching circuits 191 and 192, the low pass filter 23, and the attenuator 24 is omitted. However, these electronic components are also disposed on the first main surface 41 or the second main surface 42 of the mounting substrate 4.

### 4.2 First Electronic Component

As illustrated in FIG. 2, the first electronic component 51 is disposed on the first main surface 41 of the mounting substrate 4. In the example of FIG. 2, the first electronic component 51 is mounted on the first main surface 41 of the mounting substrate 4. Regarding the first electronic component 51, part of the first electronic component 51 may be mounted on the first main surface 41 of the mounting substrate 4 and the remaining part of the first electronic component 51 may be mounted inside the mounting substrate 4. In short, the first electronic component 51 is located closer to the first main surface 41 than to the second main surface 42 in the mounting substrate 4 and at least part of the first electronic component 51 is mounted on the first main surface 41. For example, the first electronic component 51 is an electronic component configuring the reception filter 111. That is, the reception filter 111 (second reception filter) is disposed on the first main surface 41 of the mounting substrate 4.

### 4.3 Second Electronic Component

As illustrated in FIG. 2, the second electronic component 52 is disposed on the first main surface 41 of the mounting substrate 4. In the example of FIG. 2, the second electronic component 52 is mounted on the first main surface 41 of the mounting substrate 4. Regarding the second electronic component 52, part of the second electronic component 52 may be disposed on the first main surface 41 of the mounting substrate 4 and the remaining part of the second electronic component 52 may be mounted inside the mounting substrate 4. In short, the second electronic component 52 is located closer to the first main surface 41 than to the second main surface 42 in the mounting substrate 4 and at least part of the second electronic component 52 is mounted on the first main surface 41. For example, the second electronic component 52 is an electronic component configuring the reception filter 115. That is, the reception filter 115 (first reception filter) is disposed on the first main surface 41 of the mounting substrate 4.

### 4.4 Third Electronic Component

As illustrated in FIG. 2, the third electronic component 53 is disposed on the first main surface 41 of the mounting substrate 4. In the example of FIG. 2, the third electronic component 53 is mounted on the first main surface 41 of the mounting substrate 4. Regarding the third electronic component 53, part of the third electronic component 53 may be mounted on the first main surface 41 of the mounting substrate 4 and the remaining part of the third electronic component 53 may be mounted inside the mounting substrate 4. In short, the third electronic component 53 is located closer to the first main surface 41 than to the second main surface 42 in the mounting substrate 4 and at least part of the third electronic component 53 is mounted on the first main surface 41. For example, the third electronic component 53 is an electronic component configuring the reception filter 112.

### 4.5 Fourth Electronic Component

As illustrated in FIG. 2, the fourth electronic component 54 is disposed on the first main surface 41 of the mounting substrate 4. In the example of FIG. 2, the fourth electronic component 54 is mounted on the first main surface 41 of the mounting substrate 4. Regarding the fourth electronic component 54, part of the fourth electronic component 54 may be mounted on the first main surface 41 of the mounting substrate 4 and the remaining part of the fourth electronic component 54 may be mounted inside the mounting substrate 4. In short, the fourth electronic component 54 is located closer to the first main surface 41 than to the second main surface 42 in the mounting substrate 4 and at least part of the fourth electronic component 54 is mounted on the first main surface 41. For example, the fourth electronic component 54 is an electronic component configuring the reception filter 113.

### 4.6 Fifth Electronic Component

As illustrated in FIG. 2, the fifth electronic component 55 is disposed on the first main surface 41 of the mounting substrate 4. In the example of FIG. 2, the fifth electronic component 55 is mounted on the first main surface 41 of the mounting substrate 4. Regarding the fifth electronic component 55, part of the fifth electronic component 55 may be mounted on the first main surface 41 of the mounting substrate 4 and the remaining part of the fifth electronic component 55 may be mounted inside the mounting substrate 4. In short, the fifth electronic component 55 is located closer to the first main surface 41 than to the second main surface 42 in the mounting substrate 4 and at least part of the fifth electronic component 55 is mounted on the first main surface 41. For example, the fifth electronic component 55 is an electronic component configuring the reception filter 114.

### 4.7 Sixth Electronic Component

As illustrated in FIG. 2, the sixth electronic component 56 is disposed on the first main surface 41 of the mounting substrate 4. In the example of FIG. 2, the sixth electronic component 56 is mounted on the first main surface 41 of the mounting substrate 4. Regarding the sixth electronic component 56, part of the sixth electronic component 56 may be mounted on the first main surface 41 of the mounting substrate 4 and the remaining part of the sixth electronic component 56 may be mounted inside the mounting substrate 4. In short, the sixth electronic component 56 is located closer to the first main surface 41 than to the second main surface 42 in the mounting substrate 4 and at least part of the sixth electronic component 56 is mounted on the first main surface 41. For example, the sixth electronic component 56 is an electronic component configuring the inductor L2 of the input matching circuit 172. That is, the inductor L2 (first inductor) is disposed on the first main surface 41 of the mounting substrate 4.

### 4.8 Seventh Electronic Component

As illustrated in FIG. 2, the seventh electronic component 57 is disposed on the first main surface 41 of the mounting substrate 4. In the example of FIG. 2, the seventh electronic component 57 is mounted on the first main surface 41 of the mounting substrate 4. Regarding the seventh electronic component 57, part of the seventh electronic component 57 may be mounted on the first main surface 41 of the mounting substrate 4 and the remaining part of the seventh electronic component 57 may be mounted inside the mounting substrate 4. In short, the seventh electronic component 57 is located closer to the first main surface 41 than to the second main surface 42 in the mounting substrate 4 and at least part of the seventh electronic component 57 is mounted on the first main surface 41. For example, the seventh electronic component 57 is an electronic component configuring the inductor L3 of the matching circuit 18. That is, the inductor L3 (second inductor) is disposed on the first main surface 41 of the mounting substrate 4.

### 4.9 Eighth Electronic Component

As illustrated in FIG. 2, the eighth electronic component 58 is disposed on the first main surface 41 of the mounting substrate 4. In the example of FIG. 2, the eighth electronic component 58 is mounted on the first main surface 41 of the mounting substrate 4. Regarding the eighth electronic component 58, part of the eighth electronic component 58 may be mounted on the first main surface 41 of the mounting substrate 4 and the remaining part of the eighth electronic component 58 may be mounted inside the mounting substrate 4. In short, the eighth electronic component 58 is located closer to the first main surface 41 than to the second main surface 42 in the mounting substrate 4 and at least part of the eighth electronic component 58 is mounted on the first main surface 41. For example, the eighth electronic component 58 is an electronic component configuring the inductor L1 of the input matching circuit 171. That is, the inductor L1 (third inductor) is disposed on the first main surface 41 of the mounting substrate 4.

### 4.10 Ninth Electronic Component

As illustrated in FIG. 3, the ninth electronic component 59 is disposed on the second main surface 42 of the mounting substrate 4. In the example of FIG. 3, the ninth electronic component 59 is mounted on the second main surface 42 of the mounting substrate 4. Regarding the ninth electronic component 59, part of the ninth electronic component 59 may be mounted on the second main surface 42 of the mounting substrate 4 and the remaining part of the ninth electronic component 59 may be mounted inside the mounting substrate 4. In short, the ninth electronic component 59 is located closer to the second main surface 42 than to the first main surface 41 in the mounting substrate 4 and at least part of the ninth electronic component 59 is mounted on the second main surface 42. For example, the ninth electronic component 59 is an IC chip 6. That is, the IC chip 6 is disposed on the second main surface 42 of the mounting substrate 4. The IC chip 6 includes the low noise amplifier 121, the low noise amplifier 122, and the switch 15.

### 4.11 External Connection Terminals

The plurality of external connection terminals 25 are terminals for electrically connecting the mounting substrate 4 to an external substrate (not illustrated in the drawing).

As illustrated in FIG. 3, the plurality of external connection terminals 25 are disposed on the second main surface 42 of the mounting substrate 4. “The external connection terminals 25 are disposed on the second main surface 42 of the mounting substrate 4” includes the state in which the external connection terminals 25 are mechanically connected to the second main surface 42 of the mounting substrate 4 and the state in which the external connection terminals 25 are electrically connected to (an appropriate conductor part of) the mounting substrate 4. Materials of the plurality of external connection terminals 25 are, for example, metal (for example, copper, copper alloy, etc.). Each of the plurality of external connection terminals 25 is a columnar electrode (for example, an electrode with a cylindrical shape).

### 4.12 Resin Layers and Metal Electrode Layer

The first resin layer is disposed on the first main surface 41 of the mounting substrate 4 and covers the first to eighth electronic components 51 to 58 and the first main surface 41 of the mounting substrate 4. The first resin layer has electrical insulating characteristics. The first resin layer includes resin (for example, epoxy resin). The first resin layer may include filler as well as resin.

The second resin layer is disposed on the second main surface 42 of the mounting substrate 4. The second resin layer covers an outer peripheral surface and top surface of the ninth electronic component 59 and an outer peripheral surface of each of the plurality of external connection terminals 25 that are disposed on the second main surface 42 of the mounting substrate 4. The second resin layer does not cover a main surface of the ninth electronic component 59 that is far from the mounting substrate 4. The second resin layer has electrical insulating characteristics. The second resin layer includes resin (for example, epoxy resin). The second resin layer may include filler as well as resin. A material of the second resin layer may be the same as the material of the first resin layer or may be different from the material of the first resin layer.

The metal electrode layer covers the first resin layer, the mounting substrate 4, and the second resin layer. More particularly, the metal electrode layer covers a main surface of the first resin layer that is far from the mounting substrate 4, an outer peripheral surface of the first resin layer, an outer peripheral surface of the mounting substrate 4, and an outer peripheral surface of the second resin layer. Meanwhile, the metal electrode layer does not cover a main surface of the second resin layer that is far from the mounting substrate 4.

The metal electrode layer has conductive characteristics. In the high frequency module 1, the metal electrode layer is a shield layer that is provided for the purpose of electromagnetically shielding inside and outside the high frequency module 1. The metal electrode layer is in contact with at least part of an outer peripheral surface of the ground layer included in the mounting substrate 4. Thus, the potential of the metal electrode layer may be set to be equal to the potential of the ground layer. The metal electrode layer has a multilayer structure in which a plurality of metal layers are laminated. However, the metal electrode layer does not necessarily have a multilayer structure and may be a single metal layer. The metal layer includes one or a plurality of types of metal.

### 5 Structures of Inductors

Next, structures of the inductors L1 and L2 configuring the input matching circuits 171 and 172, respectively, will be described with reference to FIG. 2. In FIG. 2, the state in which cores and wires disposed inside the sixth electronic component 56 and the eighth electronic component 58 are transparent is illustrated.

As illustrated in FIG. 2, the inductor L1 (third inductor) configuring the eighth electronic component 58 includes a core 581 and a wire 582. In the inductor L1, the wire 582 is closely wound around the full length of an axial part of the core 581 extending along a first direction D21. That is, in the example of FIG. 2, the winding central axis of the inductor L1 is along the first direction D21.

The inductor L2 (first inductor) configuring the sixth electronic component 56 includes, as illustrated in FIG. 2, a core 561 and a wire 562. Furthermore, the inductor L2 includes a first part 563 and a second part 564. The first part 563 is a part of the axial part of the core 561 around which part of the wire 562 is closely wound along the first direction D21. The second part 564 is a part of the axial part of the core 561 around which the remaining part of the wire 562 is sparsely wound along the first direction D21. That is, in the inductor L2, the first part 563 and the second part 564 are arranged next to each other along the first direction D21 on the first main surface 41 of the mounting substrate 4. “The wire 562 is sparsely wound” includes the state in which the wire 562 is not wound around the axial part of the core 561 and the state in which the wire 562 is wound around the axial part of the core 561 sparsely. In the example of FIG. 2, the wire 562 is not wound in the second part 564 of the inductor L2.

That is, the inductor L2 includes the first part 563, which is a dense part, and the second part 564, which is a sparse part. The “sparse part” includes a part in which the number of turns of the wire of the wire 562 per unit length of the core is smaller than that in the dense part, a part in which the wire 562 is wound with less than one turn, and a part in which the wire 562 is not wound.

Furthermore, as illustrated in FIG. 2, an outer size S1 of the inductor L2 (first inductor) when seen in plan view from the thickness direction D1 of the mounting substrate 4 is larger than an outer size S2 of the inductor L3 (second inductor) configuring the seventh electronic component 57. The outer sizes S1 and S2 are the areas of the inductors L2 and L3 when seen in plan view from the thickness direction D1 of the mounting substrate 4.

### 6 Layout

Next, the layout of the high frequency module 1 will be described with reference to FIGS. 2 and 3.

As described above, the first to eighth electronic components 51 to 58 are disposed on the first main surface 41 of the mounting substrate 4. Furthermore, as described above, the ninth electronic component 59 and the plurality of external connection terminals 25 are disposed on the second main surface 42 of the mounting substrate 4. In the example of FIG. 3, the ninth electronic component 59 is disposed at the center of the second main surface 42 of the mounting substrate 4, and the plurality of external connection terminals 25 are disposed around the ninth electronic component 59 in such a manner that the plurality of external connection terminals 25 surround the ninth electronic component 59.

The first electronic component 51 and the second electronic component 52 are arranged next to each other in the first direction D21. That is, the reception filter 115 (first reception filter) and the reception filter 111 (second reception filter) are arranged next to each other in the first direction D21 when seen in plan view from the thickness direction D1 of the mounting substrate 4. More particularly, in the first direction D21, the first electronic component 51 and the second electronic component 52 are adjacent to each other. “The first electronic component 51 and the second electronic component 52 are adjacent to each other” represents the state in which the first electronic component 51 and the second electronic component 52 are arranged without necessarily another electronic component interposed therebetween. In the first embodiment, the first direction D21 is a direction that is orthogonal to the thickness direction D1 of the mounting substrate 4 and is a direction along the longitudinal direction of the mounting substrate 4 (left-right direction in FIG. 2).

The second electronic component 52 and the third electronic component 53 are arranged next to each other in the first direction D21. More particularly, in the first direction D21, the second electronic component 52 and the third electronic component 53 are adjacent to each other. Furthermore, the third electronic component 53, the fourth electronic component 54, and the fifth electronic component 55 are arranged in this order in a second direction D22, which is orthogonal to the first direction D21. More particularly, in the second direction D22, the third electronic component 53 and the fourth electronic component 54 are adjacent to each other and the fourth electronic component 54 and the fifth electronic component 55 are adjacent to each other. In the first embodiment, the second direction D22 is a direction (orthogonal direction) that is orthogonal to both the thickness direction D1 of the mounting substrate 4 and the first direction D21 and is a direction along the lateral direction of the mounting substrate 4 (top-bottom direction in FIG. 2).

The first electronic component 51 and the sixth electronic component 56 are arranged next to each other in the second direction D22. That is, the reception filter 111 (second reception filter) and the inductor L2 (first inductor) are arranged next to each other in the second direction D22 when seen in plan view from the thickness direction D1 of the mounting substrate 4. More particularly, in the second direction D22, the first electronic component 51 and the sixth electronic component 56 are adjacent to each other.

Furthermore, the second electronic component 52 and the seventh electronic component 57 are arranged next to each other in the second direction D22. That is, the reception filter 115 (first reception filter) and the inductor L3 (second inductor) are arranged next to each other in the second direction D22 when seen in plan view from the thickness direction D1 of the mounting substrate 4. More particularly, in the second direction D22, the second electronic component 52 and the seventh electronic component 57 are adjacent to each other.

In the second direction D22, the eighth electronic component 58 is arranged farther away from the second electronic component 52 than the seventh electronic component 57 is. That is, in the second direction D22, the inductor L3 (second inductor) is disposed between the inductor L1 (third inductor) and the reception filter 115 (first reception filter).

As illustrated in FIG. 2, the inductor L2 configuring the sixth electronic component 56 is arranged in such a manner that the first part 563 is near the first electronic component 51 and the second part 564 is near the second electronic component 52 in the first direction D21 when seen in plan view from the thickness direction D1 of the mounting substrate 4. Thus, in the second direction D22, the first part 563 of the inductor L2 and the reception filter 115 do not overlap. “The first part 563 of the inductor L2 and the reception filter 115 do not overlap” includes the state in which part of the first part 563 of the inductor L2 and the reception filter 115 do not overlap and the state in which the entire first part 563 of the inductor L2 and the reception filter 115 do not overlap. That is, “the first part 563 of the inductor L2 and the reception filter 115 do not overlap” represents the state in which at least part of the first part 563 of the inductor L2 and the reception filter 115 do not overlap. In the high frequency module 1 according to the first embodiment, the second direction D22 corresponds to an orthogonal direction.

### 7 Effects

The high frequency module 1 according to the first embodiment includes the reception filter 115 (first reception filter), the reception filter 111 (second reception filter), the low noise amplifier 122, the inductor L2 (first inductor), the inductor L3 (second inductor), and the mounting substrate 4. The reception filter 115 has a pass band including a first reception band. The reception filter 111 has a pass band including a second reception band that is different from the first reception band. The inductor L2 includes the core 561 and the wire 562 and is connected between the reception filter 115 and the low noise amplifier 122. The inductor L3 is connected to the output terminal of the reception filter 111. The mounting substrate 4 has the first main surface 41 and the second main surface 42 that are opposite to each other. The reception filter 115, the reception filter 111, the inductor L2, and the inductor L3 are disposed on the first main surface 41 of the mounting substrate 4. The outer size S1 of the inductor L2 is larger than the outer size S2 of the inductor L3 when seen in plan view from the thickness direction D1 of the mounting substrate 4. The inductor L2 includes the first part 563 around which part of the wire 562 is closely wound and the second part 564 around which the remaining part of the wire 562 is sparsely wound. In the second direction D22 that is orthogonal to the thickness direction D1, the first part 563 of the inductor L2 and the reception filter 115 do not overlap.

In the high frequency module 1 according to the first embodiment, since the part around which part of the wire 562 of the inductor L2 is closely wound and the reception filter 115 do not overlap in the second direction D22 that is orthogonal to the thickness direction D1 of the mounting substrate 4, an electromagnetic field of the inductor L2 can be prevented from interfering with the reception filter 115, and a deterioration in attenuation characteristics of the reception filter 115 can be reduced.

The high frequency module 1 according to the first embodiment includes the reception filter 115 (first reception filter), the reception filter 111 (second reception filter), the low noise amplifier 122, the inductor L2 (first inductor), the inductor L3 (second inductor), and the mounting substrate 4. The reception filter 115 has a pass band including a first reception band. The reception filter 111 has a pass band including a second reception band that is different from the first reception band. The inductor L2 includes the core 561 and the wire 562 and is connected between the reception filter 115 and the low noise amplifier 122. The inductor L3 is connected to the output terminal of the reception filter 111. The mounting substrate 4 has the first main surface 41 and the second main surface 42 that are opposite to each other. The reception filter 115, the reception filter 111, the inductor L2, and the inductor L3 are disposed on the first main surface 41 of the mounting substrate 4. The outer size S1 of the inductor L2 is larger than the outer size S2 of the inductor L3 when seen in plan view from the thickness direction D1 of the mounting substrate 4. In the first direction D21 that is orthogonal to the thickness direction D1, the reception filter 115 and the reception filter 111 are arranged next to each other when seen in plan view from the thickness direction DI of the mounting substrate 4. In the second direction D22 that is orthogonal to both the thickness direction Dl and the first direction D21, the reception filter 111 and the inductor L2 are arranged next to each other and the reception filter 115 and the inductor L3 are arranged next to each other when seen in plan view from the thickness direction D1 of the mounting substrate 4.

In the high frequency module 1 according to the first embodiment, the reception filter 115 and the reception filter 111 are adjacent to each other in the first direction D21 that is orthogonal to the thickness direction D1 of the mounting substrate 4, and the inductor L2 and the reception filter 111 are adjacent to each other and the inductor L3 and the reception filter 115 are adjacent to each other in the second direction D22 that is orthogonal to both the thickness direction D1 of the mounting substrate 4 and the first direction D21. That is, since the inductor L2 and the reception filter 115 do not overlap in the second direction D22, an electromagnetic field of the inductor L2 can be prevented from interfering with the reception filter 115, and a deterioration in the attenuation characteristics of the reception filter 115 can be reduced.

Furthermore, in the high frequency module 1 according to the first embodiment, by arranging the three inductors L1 to L3 for the five reception filters 111 to 115, characteristics of the five reception filters 111 to 115 can be satisfied. As a result, a reduction in the size of the high frequency module 1 can also be achieved.

Furthermore, in the high frequency module 1 according to the first embodiment, the inductor L3 (second inductor) is disposed between the inductor L1 (third inductor) and the reception filter 115 (first reception filter) in the second direction D22. Thus, a deterioration in the attenuation characteristics of a filter caused by electromagnetic coupling between the inductor L1 and the inductor L3 can be reduced.

In the high frequency module 1 according to the first embodiment, characteristics of a plurality of reception filters (in the example illustrated in a drawing, the reception filters 114 and 115) can be satisfied by the inductor L2 (first inductor) connected to the common terminal 140B of the switch 14.

Furthermore, in the high frequency module 1 according to the first embodiment, the low noise amplifiers 121 and 122 and the switch 15 are included in a single IC chip 6. Thus, a reduction in the size of the mounting substrate 4 when seen in plan view from the thickness direction D1 of the mounting substrate 4 can be achieved.

Furthermore, in the high frequency module 1 according to the first embodiment, the IC chip 6 is disposed on the second main surface 42 of the mounting substrate 4. Thus, a further reduction in the size of the mounting substrate 4 when seen in plan view from the thickness direction D1 of the mounting substrate 4 can be achieved.

### 8 Modification

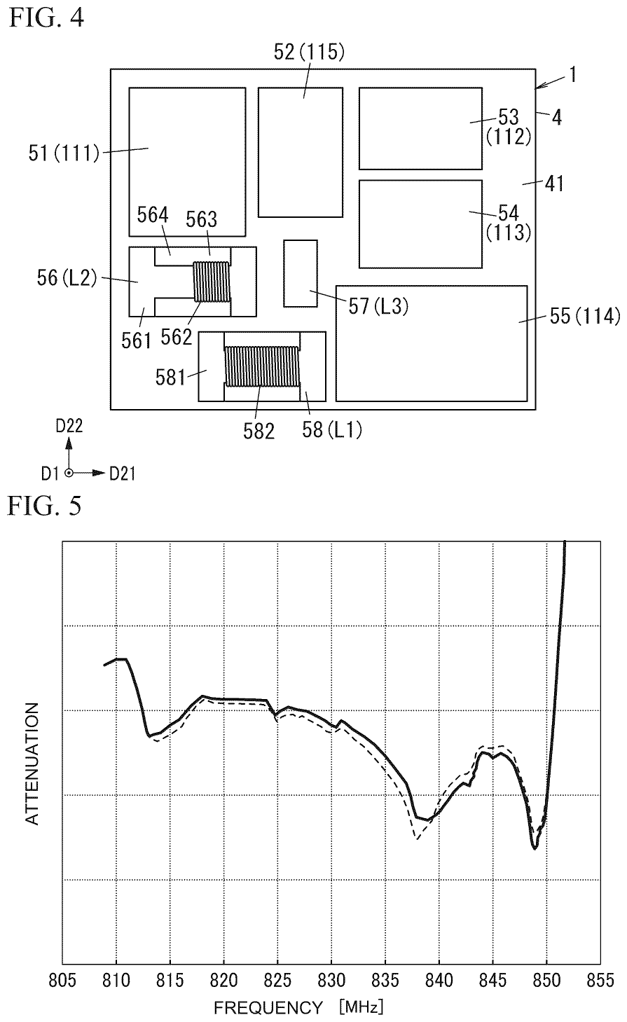

Next, the high frequency module 1 according to a modification of the first embodiment will be described with reference to FIGS. 4 and 5.

In the high frequency module 1 according to the first embodiment, as illustrated in FIG. 2, the inductor L2 configuring the sixth electronic component 56 is arranged with an orientation in which the first part 563 is near the first electronic component 51 and the second part 564 is near the second electronic component 52 in the first direction D21. In contrast, the inductor L2 may be arranged with an orientation in which the second part 564 is near the first electronic component 51 and the first part 563 is near the second electronic component 52 in the first direction D21, as illustrated in FIG. 4. Also in this case, as illustrated in FIG. 4, it is desirable that the first part 563 of the inductor L2 (first inductor) and the reception filter 115 (first reception filter) do not overlap in the second direction D22 (orthogonal direction) that is orthogonal to the thickness direction D1 of the mounting substrate 4.

FIG. 5 is a graph indicating attenuation characteristics in a transmission band of a reception signal in Band 26 passing through the reception filter 115. In FIG. 5, a solid line represents attenuation characteristics corresponding to the arrangement example illustrated in FIG. 2, and a broken line represents attenuation characteristics corresponding to the arrangement example illustrated in FIG. 4. Referring to FIG. 5, there is little variation between the attenuation characteristics based on the arrangement example illustrated in FIG. 2 and the attenuation characteristics based on the arrangement example illustrated in FIG. 4. That is, with the high frequency module 1, variations in attenuation characteristics depending on the orientation of the inductor L2 in the first direction D21 can be reduced.

Also with the high frequency module 1 according to the modification of the first embodiment, both reducing a deterioration in the attenuation characteristics of a filter and reducing the size can be achieved, as with the high frequency module 1 according to the first embodiment.

### SECOND EMBODIMENT

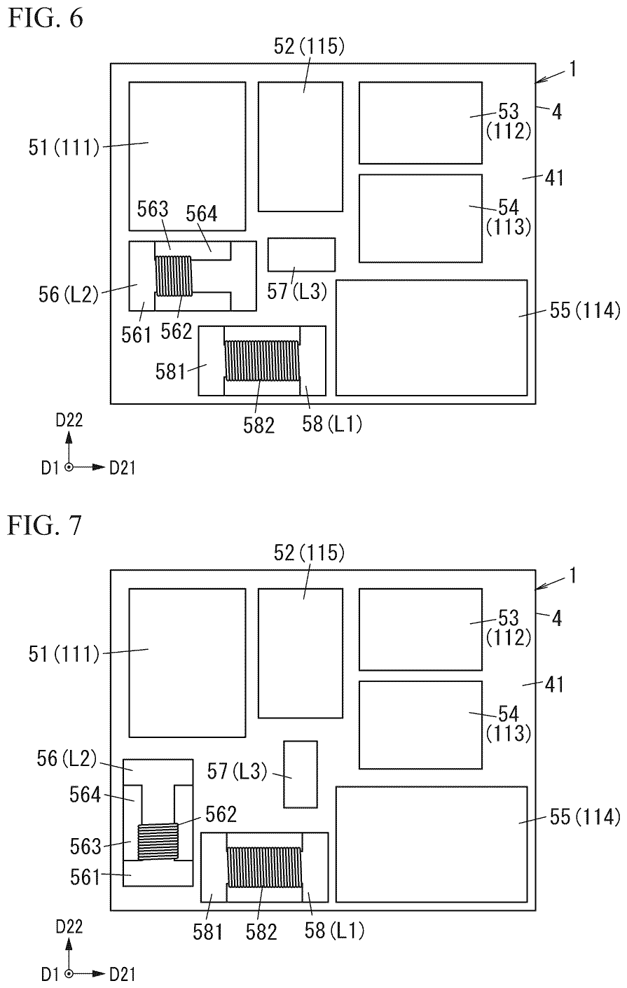

The high frequency module 1 according to a second embodiment will be described with reference to FIG. 6. Component elements of the high frequency module 1 according to the second embodiment that are similar to those of the high frequency module 1 according to the first embodiment (see FIGS. 2 and 3) will be denoted by the same signs and description of those component elements will be omitted.

As illustrated in FIG. 6, the high frequency module 1 according to the second embodiment is different from the high frequency module 1 according to the first embodiment in that the orientation of the seventh electronic component 57 configuring the inductor L3 in the high frequency module 1 according to the second embodiment is different from that in the high frequency module 1 according to the first embodiment by 90 degrees when seen in plan view from the thickness direction D1 of the mounting substrate 4.

That is, in the high frequency module 1 according to the second embodiment, the seventh electronic component 57 is disposed on the first main surface 41 of the mounting substrate 4 with an orientation in which the longitudinal direction of the seventh electronic component 57 is along the first direction D21 and the lateral direction of the seventh electronic component 57 is along the second direction D22.

Also with the high frequency module 1 according to the second embodiment, both reducing a deterioration in the attenuation characteristics of a filter and reducing the size can be achieved, as with the high frequency module 1 according to the first embodiment.

Also in the high frequency module 1 according to the second embodiment, the inductor L2 may be disposed on the first main surface 41 of the mounting substrate 4 with an orientation in which the second part 564 is near the first electronic component 51 and the first part 563 is near the second electronic component 52 in the first direction D21, as in the high frequency module 1 according to the modification of the first embodiment.

### THIRD EMBODIMENT

The high frequency module 1 according to a third embodiment will be described with reference to FIG. 7. Component elements of the high frequency module 1 according to the third embodiment that are similar to those of the high frequency module 1 according to the first embodiment (see FIGS. 2 and 3) will be denoted by the same signs and description of those component elements will be omitted.

As illustrated in FIG. 7, the high frequency module 1 according to the third embodiment is different from the high frequency module 1 according to the first embodiment in that the orientation of the sixth electronic component 56 configuring the inductor L2 in the high frequency module 1 according to the third embodiment is different from that in the high frequency module 1 according to the first embodiment by 90 degrees when seen in plan view from the thickness direction D1 of the mounting substrate 4.

That is, in the high frequency module 1 according to the third embodiment, the sixth electronic component 56 is disposed on the first main surface 41 of the mounting substrate 4 with an orientation in which the longitudinal direction of the sixth electronic component 56 is along the second direction D22 and the lateral direction of the sixth electronic component 56 is along the first direction D21. More particularly, the sixth electronic component 56 is disposed on the first main surface 41 of the mounting substrate 4 in such a manner that the winding central axis of the inductor L2 is along the second direction D22.

In this case, as illustrated in FIG. 7, it is desirable that the inductor L2 be disposed on the first main surface 41 of the mounting substrate 4 with an orientation in which the second part 564 is near the first electronic component 51 and the first part 563 is far from the first electronic component 51 in the second direction D22.

Also with the high frequency module 1 according to the third embodiment, both reducing a deterioration in the attenuation characteristics of a filter and reducing the size can be achieved, as with the high frequency module 1 according to the first embodiment.

The inductor L2 may be disposed on the first main surface 41 of the mounting substrate 4 with an orientation in which the first part 563 is near the first electronic component 51 and the second part 564 is far from the first electronic component 51 in the second direction D22.

### FOURTH EMBODIMENT

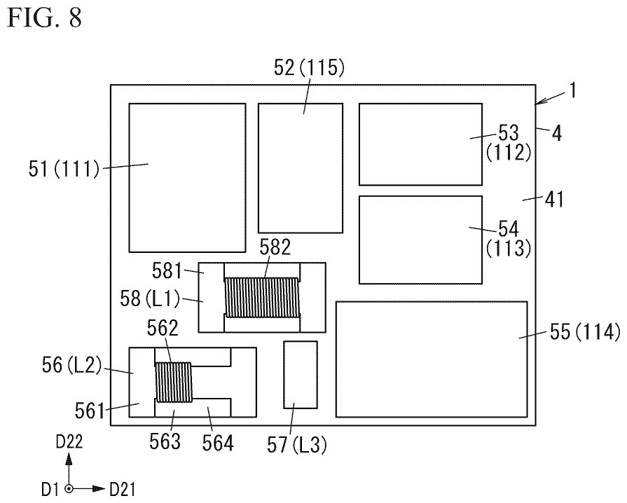

The high frequency module 1 according to a fourth embodiment will be described with reference to FIG. 8. Component elements of the high frequency module 1 according to the fourth embodiment that are similar to those of the high frequency module 1 according to the first embodiment (see FIGS. 2 and 3) will be denoted by the same signs and description of those component elements will be omitted.

As illustrated in FIG. 8, the high frequency module 1 according to the fourth embodiment is different from the high frequency module 1 according to the first embodiment in that the eighth electronic component 58 configuring the inductor L1 is disposed between the second electronic component 52 configuring the reception filter 115 and the seventh electronic component 57 configuring the inductor L3 in the second direction D22 when seen in plan view from the thickness direction D1 of the mounting substrate 4.

That is, in the high frequency module 1 according to the fourth embodiment, the inductor L1, which is the third inductor, is disposed between the inductor L3, which is the second inductor, and the reception filter 115, which is the first reception filter, in the second direction D22 when seen in plan view from the thickness direction D1 of the mounting substrate 4.

Also with the high frequency module 1 according to the fourth embodiment, both reducing a deterioration in the attenuation characteristics of a filter and reducing the size can be achieved, as with the high frequency module 1 according to the first embodiment.

Also in the high frequency module 1 according to the fourth embodiment, the inductor L2 may be disposed on the first main surface 41 of the mounting substrate 4 with an orientation in which the second part 564 is near the first electronic component 51 and the first part 563 is near the second electronic component 52 in the first direction D21, as in the high frequency module 1 according to the modification of the first embodiment.

### Aspects

Aspects described below are disclosed herein.

A high frequency module (1) according to a first aspect includes a first reception filter (115), a second reception filter (111), a first low noise amplifier (122), a first inductor (L2), a second inductor (L3), and a mounting substrate (4). The first reception filter (115) has a pass band including a first reception band. The second reception filter (111) has a pass band including a second reception band that is different from the first reception band. The first inductor (L2) includes a core (561) and a wire (562) and is connected between the first reception filter (115) and the first low noise amplifier (122). The second inductor (L3) is connected to an output terminal of the second reception filter (111). The mounting substrate (4) has a first main surface (41) and a second main surface (42) that are opposite to each other. The first reception filter (115), the second reception filter (111), the first inductor (L2), and the second inductor (L3) are disposed on the first main surface (41) of the mounting substrate (4). An outer size (S1) of the first inductor (L2) is larger than an outer size (S2) of the second inductor (L3) when seen in plan view from a thickness direction (D1) of the mounting substrate (4). The first inductor (L2) includes a first part (563) around which part of the wire (562) is closely wound and a second part (564) around which a remaining part of the wire (562) is sparsely wound. In an orthogonal direction (D22) that is orthogonal to the thickness direction (D1), the first part (563) of the first inductor (L2) and the first reception filter (115) do not overlap.

According to this aspect, a deterioration in attenuation characteristics of a filter can be reduced.

A high frequency module (1) according to a second aspect includes a first reception filter (115), a second reception filter (111), a first low noise amplifier (122), a first inductor (L2), a second inductor (L3), and a mounting substrate (4). The first reception filter (115) has a pass band including a first reception band. The second reception filter (111) has a pass band including a second reception band that is different from the first reception band. The first inductor (L2) includes a core (561) and a wire (562) and is connected between the first reception filter (115) and the first low noise amplifier (122). The second inductor (L3) is connected to an output terminal of the second reception filter (111). The mounting substrate (4) has a first main surface (41) and a second main surface (42) that are opposite to each other. The first reception filter (115), the second reception filter (111), the first inductor (L2), and the second inductor (L3) are disposed on the first main surface (41) of the mounting substrate (4). When seen in plan view from a thickness direction (D1) of the mounting substrate (4), an outer size (S1) of the first inductor (L2) is larger than an outer size (S2) of the second inductor (L3). When seen in plan view from the thickness direction (D1) of the mounting substrate (4), in a first direction (D21) that is orthogonal to the thickness direction (D1), the first reception filter (115) and the second reception filter (111) are arranged next to each other. When seen in plan view from the thickness direction (D1) of the mounting substrate (4), in a second direction (D22) that is orthogonal to both the thickness direction (D1) and the first direction (D21), the second reception filter (111) and the first inductor (L2) are arranged next to each other and the first reception filter (115) and the second inductor (L3) are arranged next to each other.

According to this aspect, a deterioration in attenuation characteristics of a filter can be reduced.

According to a third aspect, the high frequency module (1) according to the first aspect further includes a second low noise amplifier (121) and a third inductor (L1). The third inductor (L1) includes a core (581) and a wire (582) and is connected between the second reception filter (111) and the second low noise amplifier (121). The third inductor (L1) is disposed on the first main surface (41) of the mounting substrate (4). One of the second inductor (L3) and the third inductor (L1) is disposed between the other one of the second inductor (L3) and the third inductor (L1) and the first reception filter (115) in the orthogonal direction (D22).

According to this aspect, a deterioration in the attenuation characteristics of the filter caused by electromagnetic coupling between the second inductor (L3) and the third inductor (L1) can be reduced.

According to a fourth aspect, the high frequency module (1) according to the second aspect further includes a second low noise amplifier (121) and a third inductor (L1). The third inductor (L1) includes a core (581) and a wire (582) and is connected between the second reception filter (111) and the second low noise amplifier (121). The third inductor (L1) is disposed on the first main surface (41) of the mounting substrate (4). When seen in plan view from the thickness direction (D1) of the mounting substrate (4), in the second direction (D22), the second inductor (L3) is disposed between the third inductor (L1) and the first reception filter (115).

According to this aspect, a deterioration in the attenuation characteristics of the filter caused by electromagnetic coupling between the second inductor (L3) and the third inductor (L1) can be reduced.

According to a fifth aspect, the high frequency module (1) according to any one of the first to fourth aspects further includes a second low noise amplifier (121), a first switch (14), and a third inductor (L1). The first switch (14) includes a first common terminal (140B), a second common terminal (140A), a first selection terminal (142), and a second selection terminal (141). The third inductor (L1) includes a core (581) and a wire (582) and is connected between the second reception filter (111) and the second low noise amplifier (121). The first selection terminal (142) is connected to an output terminal of the first reception filter (115). The second selection terminal (141) is connected to the output terminal of the second reception filter (111) with the second inductor (L3) interposed therebetween. The first common terminal (140B) is connected to an input terminal of the first low noise amplifier (122) with the first inductor (L2) interposed therebetween. The second common terminal (140A) is connected to an input terminal of the second low noise amplifier (121) with the third inductor (L1) interposed therebetween.

According to this aspect, with the first inductor (L2) that is connected to the first common terminal (140B) of the first switch (14), characteristics of a plurality of reception filters (reception filters 114 and 115) can be satisfied.

According to a sixth aspect, the high frequency module (1) according to the fifth aspect further includes a second low noise amplifier (121). The first low noise amplifier (122), the second low noise amplifier (121), and the first switch (14) are included in a single IC chip (6).

According to this aspect, a reduction in the size of the mounting substrate (4) when seen in plan view from the thickness direction (D1) of the mounting substrate (4) can be achieved.

According to a seventh aspect, in the high frequency module (1) according to the sixth aspect, the IC chip (6) is disposed on the second main surface (42) of the mounting substrate (4).

According to this aspect, a further reduction in the size of the mounting substrate (4) when seen in plan view from the thickness direction (D1) of the mounting substrate (4) can be achieved.

According to an eighth aspect, the high frequency module (1) according to any one of the fifth to seventh aspects further includes antenna terminals (251, 252) and a second switch (13). The second switch (13) is connected between an input terminal of the first reception filter (115) and an input terminal of the second reception filter (111), and the antenna terminals (251, 252).

According to a ninth aspect, in the high frequency module (1) according to any one of the first to eighth aspects, the first reception band is Band 26, Band 8, Band 12, Band 29, Band 13, Band 14, Band 28, or Band 20 based on 3GPP LTE standards.

According to a tenth aspect, in the high frequency module (1) according to any one of the first to ninth aspects, the second reception band is Band 71 based on 3GPP LTE standards.

A communication apparatus (10) according to an eleventh aspect includes the high frequency module (1) according to any one of the first to tenth aspects and a signal processing circuit (2). The signal processing circuit (2) is connected to the high frequency module (1).

According to this aspect, a deterioration in the attenuation characteristics of the filter can be reduced.

What is claimed is:

1. A high frequency module comprising:
a first reception filter that has a pass band comprising a first reception band;
a second reception filter that has a pass band comprising a second reception band that is different from the first reception band;
a first low noise amplifier;
a first inductor that comprises a first core and a first wire, and that is connected between the first reception filter and the first low noise amplifier;
a second inductor that is connected to an output terminal of the second reception filter; and
a mounting substrate that has a first main surface and a second main surface that are opposite to each other,
wherein the first reception filter, the second reception filter, the first inductor, and the second inductor are on the first main surface of the mounting substrate,
wherein an outer size of the first inductor is larger than an outer size of the second inductor, as seen in a plan view of the mounting substrate,
wherein the first inductor includes:
a first part around which part of the first wire is closely wound, and
a second part around which a remaining part of the first wire is sparsely wound, and
wherein the first part of the first inductor and the first reception filter do not overlap in a direction that is orthogonal to a thickness direction of the mounting substrate.

2. A high frequency module comprising:
a first reception filter that has a pass band comprising a first reception band;
a second reception filter that has a pass band comprising a second reception band that is different from the first reception band;
a first low noise amplifier;
a first inductor that comprises a first core and a first wire, and that is connected between the first reception filter and the first low noise amplifier;
a second inductor that is connected to an output terminal of the second reception filter; and
a mounting substrate that has a first main surface and a second main surface that are opposite to each other,
wherein the first reception filter, the second reception filter, the first inductor, and the second inductor are on the first main surface of the mounting substrate, and
wherein as seen in a plan view of the mounting substrate:
an outer size of the first inductor is larger than an outer size of the second inductor,
the first reception filter and the second reception filter are arranged next to each other in a first direction that is orthogonal to a thickness direction of the mounting substrate, and
the second reception filter, and the first inductor are arranged next to each other, and the first reception filter and the second inductor are arranged next to each other, in a second direction that is orthogonal to both the thickness direction and the first direction.

3. The high frequency module according to claim 1, further comprising:
a second low noise amplifier; and
a third inductor that comprises a third core and a third wire, and that is connected between the second reception filter and the second low noise amplifier,
wherein the third inductor is on the first main surface of the mounting substrate, and
wherein one of the second inductor and the third inductor is between the first reception filter and the other one of the second inductor and the third inductor, in the orthogonal direction.

4. The high frequency module according to claim 2, further comprising:
a second low noise amplifier; and
a third inductor that comprises a third core and a third wire, and that is connected between the second reception filter and the second low noise amplifier,
wherein the third inductor is on the first main surface of the mounting substrate, and
wherein the second inductor is between the third inductor and the first reception filter in the second direction.

5. The high frequency module according to claim 1, further comprising:
a second low noise amplifier;
a first switch that comprises a first common terminal, a second common terminal, a first selection terminal, and a second selection terminal; and
a third inductor that comprises a third core and a third wire, and that is connected between the second reception filter and the second low noise amplifier,
wherein the first selection terminal is connected to an output terminal of the first reception filter,
wherein the second selection terminal is connected to the output terminal of the second reception filter with the second inductor interposed therebetween,
wherein the first common terminal is connected to an input terminal of the first low noise amplifier with the first inductor interposed therebetween, and
wherein the second common terminal is connected to an input terminal of the second low noise amplifier with the third inductor interposed therebetween.

6. The high frequency module according to claim 2, further comprising:
a second low noise amplifier;
a first switch that comprises a first common terminal, a second common terminal, a first selection terminal, and a second selection terminal; and
a third inductor that comprises a third core and a third wire, and that is connected between the second reception filter and the second low noise amplifier,
wherein the first selection terminal is connected to an output terminal of the first reception filter,
wherein the second selection terminal is connected to the output terminal of the second reception filter with the second inductor interposed therebetween,
wherein the first common terminal is connected to an input terminal of the first low noise amplifier with the first inductor interposed therebetween, and
wherein the second common terminal is connected to an input terminal of the second low noise amplifier with the third inductor interposed therebetween.

7. The high frequency module according to claim 5, wherein the first low noise amplifier, the second low noise amplifier, and the first switch are in a single integrated circuit (IC) chip.

8. The high frequency module according to claim 6, wherein the first low noise amplifier, the second low noise amplifier, and the first switch are in a single integrated circuit (IC) chip.

9. The high frequency module according to claim 7, wherein the IC chip is on the second main surface of the mounting substrate.

10. The high frequency module according to claim 8, wherein the IC chip is on the second main surface of the mounting substrate.

11. The high frequency module according to claim 5, further comprising:
a plurality of antenna terminals; and
a second switch,
wherein the second switch is connected between an input terminal of the first reception filter and an input terminal of the second reception filter, and the plurality of antenna terminals.

12. The high frequency module according to claim 6, further comprising:
a plurality of antenna terminals; and
a second switch,
wherein the second switch is connected between an input terminal of the first reception filter and an input terminal of the second reception filter, and the plurality of antenna terminals.

13. The high frequency module according to claim 1, wherein the first reception band is Band 26, Band 8, Band 12, Band 29, Band 13, Band 14, Band 28, or Band 20 based on Third Generation Partnership Project (3GPP) Long Term Evolution (LTE) standards.

14. The high frequency module according to claim 2, wherein the first reception band is Band 26, Band 8, Band 12, Band 29, Band 13, Band 14, Band 28, or Band 20 based on Third Generation Partnership Project (3GPP) Long Term Evolution (LTE) standards.

15. The high frequency module according to claim 1, wherein the second reception band is Band 71 based on Third Generation Partnership Project (3GPP) Long Term Evolution (LTE) standards.

16. The high frequency module according to claim 2, wherein the second reception band is Band 71 based on Third Generation Partnership Project (3GPP) Long Term Evolution (LTE) standards.

17. A communication apparatus comprising:
the high frequency module according to claim 1; and
a signal processing circuit that is connected to the high frequency module.

18. A communication apparatus comprising:
the high frequency module according to claim 2; and
a signal processing circuit that is connected to the high frequency module.
